(19) United States
(12) Patent Application Publication
(10) Pub. No.: US 2026/0160899 A1
(43) Pub. Date: Jun. 11, 2026

(54) HYBRID-POWERED ASSET TRACKING DEVICE

(71) Applicant: Nano and Advanced Materials Institute Limited, Hong Kong (HK)

(72) Inventors: Yam CHONG, Hong Kong (HK); Ka Chun LAU, Hong Kong (HK); Cheuk Yin LEE, Hong Kong (HK); Shengbo LU, Hong Kong (HK); Chenmin LIU, Hong Kong (HK)

(21) Appl. No.: 19/336,538

(22) Filed: Sep. 23, 2025

Related U.S. Application Data
(60) Provisional application No. 63/728,174, filed on Dec. 5, 2024.

(30) Foreign Application Priority Data
Dec. 5, 2024 (HK) 32024100502.6

(51) Int. Cl. G01S 19/34; G01S 19/25; H02J 7/00; H02J 7/35; H05K 5/00; H05K 5/06

(52) U.S. Cl. CPC G01S 19/34; G01S 19/252; H02J 7/35; H02J 7/64; H05K 5/0052; H05K 5/061; H02J 2207/20

(57) ABSTRACT

A long-lifespan hybrid-powered asset tracking device with solar charging capabilities operable under high and low light irradiance conditions is provided. The device includes a system controller with power-saving management logic, a communication assembly, a battery assembly, a vibration sensor module, and an occupancy detection module. The communication assembly is coupled to the system controller and provides location determination and data exchange in indoor and outdoor environments. The battery assembly comprises a solar panel module, a primary battery module, and a secondary battery module for charging the secondary battery module using energy from the solar panel module and the primary battery module. The vibration sensor module cooperates with the power-saving management logic to limit data exchanges with a cloud server when no movement is detected. The occupancy detection module detects whether an object is present within a predefined perimeter and limits data exchanges when no objects are detected.

### CROSS-REFERENCE TO RELATED APPLICATIONS

The present application claims priority from a U.S. provisional patent application Ser. No. 63/728,174 filed Dec. 5, 2024 and priority from a Hong Kong short-term patent application serial number 32024100502 filed Dec. 5, 2024, and the disclosure of which is incorporated by reference in its entirety.

### TECHNICAL FIELD

The present disclosure belongs to the technical field of wireless tracking systems; more particularly, relates to long-life wireless tracking devices that can be powered by solar energy along with non-solar energy.

### BACKGROUND

Asset trackers are typically small, rugged devices that rely on a combination of positioning and communication technologies to relay information about an asset's location and condition. They are commonly used in industries like logistics, transportation, supply chain management, and security to ensure the efficient movement and protection of valuable items. Asset trackers often include a Global Navigation Satellite System (GNSS) receiver for outdoor location tracking, along with supplementary connectivity features like Wi-Fi, Bluetooth, or cellular networks for indoor tracking or areas where GNSS signals are weak. These devices can range from simple tags that provide occasional location updates to sophisticated units capable of offering real-time data on location, movement, temperature, and more.

GNSS for asset trackers includes systems like GPS, GLONASS, BDS, and GALILEO. These systems provide highly accurate, global location data. GNSS-based trackers are ideal for outdoor environments where a direct line of sight to satellites is available. To enhance accuracy in indoor settings or urban canyons where satellite signals might be blocked, asset trackers often use Wi-Fi Access Points or Bluetooth Beacons to determine location. This approach, known as hybrid positioning, uses nearby devices as references to estimate a device's position. Asset trackers may also use cellular triangulation when GNSS and other signals are unavailable. Cellular networks provide a broad coverage area and are often used as a fallback for location tracking.

In recent years, solar-powered asset trackers have gained popularity due to their ability to extend the device's operational lifespan without frequent battery replacements. These devices use solar panels, often made from high efficiency monocrystalline cells, to generate power, which is stored in internal rechargeable batteries. Even with solar power, asset trackers commonly include lithium-ion or other rechargeable batteries to ensure continuous operation when solar energy is unavailable, such as during nighttime or prolonged periods indoors.

Asset trackers are heavily used to monitor the movement of goods through the supply chain, helping companies manage inventory, reduce losses, and optimize logistics. In transportation, asset trackers are used to track vehicles, monitor their routes, and optimize their operations. Asset tracking in the construction industry helps monitor the location of expensive machinery and tools, preventing theft and misuse. Farmers use asset trackers to monitor the movement of livestock or the location of equipment across large fields. Trackers can be embedded into valuable items for anti-theft purposes, alerting owners if the item is moved or tampered with.

However, powering asset trackers for long-term use remains a challenge for the asset tracking industry. Commercially available asset trackers are typically bulky and have a narrow operating temperature range. Power optimization features are often required, for example, sleep modes, in order to prolong tracker life. For solar-powered trackers, use is typically limited to outdoor environments. For indoor asset trackers, charging options are limited. Further, these power-conservation designs often are included in the expense of functional features, for example, the number of reports that the asset tracker can generate is restricted, resulting in unsatisfactory tracker use and performance. Therefore, power optimization features under the current state of the art are inadequate solutions.

As more and more power-consuming functionalities in asset trackers are demanded, these asset trackers need reliable power sources that are able to provide higher power to the devices. Thus, there is a need in the art for improved asset trackers with power supplies that enable advanced functionality while still providing an acceptably long lifespan.

### SUMMARY OF INVENTION

It is an objective of the present invention to provide long-life wireless tracking devices that can be powered by solar energy along with non-solar energy, thereby addressing the aforementioned shortcomings and unmet needs in the state of the art.

To solve the problems associated with previous asset trackers, the present invention provides a long-lifespan hybrid powered asset tracker with solar charging capabilities under both high and low light irradiance circumstances. The asset tracker includes one or more satellite positioning module and wireless connectivity modules, for determining the asset tracker location in indoor and/or environments. To power the asset tracker, a solar panel and a battery system including at least a primary battery and a secondary battery are provided. A battery management system is provided for charging the secondary battery using power from the solar panel and the primary battery.

In accordance with an aspect of the present invention, a long-lifespan hybrid-powered asset tracking device with solar charging capabilities operable under both high and low light irradiance conditions is provided. The asset tracking device includes a system controller, a communication assembly, a battery assembly, a vibration sensor module, and an occupancy detection module. The system controller comprises a power-saving management logic component. The communication assembly is coupled to the system controller and is configured to provide location determination and data exchange for the asset tracking device in indoor and/or outdoor environments. The battery assembly is coupled to the system controller and comprises a solar panel module, a primary battery module, a secondary battery module, and a battery management module. The battery management module is configured to charge the secondary battery module using energy from the solar panel module and the primary battery module. The vibration sensor module is coupled to the system controller and is configured to detect movement of the asset tracking device. The power-saving management logic component is configured to cooperate with the vibration sensor module to limit a number of data exchanges between the asset tracking device and a cloud server when the vibration sensor module determines that no movement of the asset tracking device is present. The occupancy detection module is coupled to the system controller and is configured to detect whether an object is present within a predefined perimeter and to limit a number of data exchanges between the asset tracking device and the cloud server using the power-saving management logic component when no objects are detected.

In one embodiment, the communication assembly comprises a GNSS receiver module configured to obtain satellite signals from GPS, GLONASS, BDS, or GALILEO.

In one embodiment, the GNSS receiver module supports Assisted GPS (A-GPS) and is configured to obtain a cold-start position fix in under about 5.5 seconds and a hot-start position fix in under about 2 seconds.

In one embodiment, the communication assembly comprises a Wi-Fi module configured to detect Wi-Fi access points for indoor positioning and data exchange.

In one embodiment, the communication assembly comprises a Bluetooth Low Energy (BLE) module configured to detect Bluetooth beacons for indoor positioning and data exchange.

In one embodiment, the communication assembly comprises a cellular communication module configured to provide NB-IoT, 4G, or 5G connectivity for uploading telemetry to the cloud server.

In one embodiment, the cellular communication module supports a power saving mode (PSM) to reduce current consumption during idle states.

In one embodiment, the hybrid-powered asset tracking device further comprises: an NFC controller coupled to the system controller and configured to exchange data with an NFC reader and to activate the asset tracking device from a deep sleep mode or an ex-factory mode.

In one embodiment, the communication assembly is configured to provide multiple communication options including Wi-Fi, BLE, and a cellular network, thereby enabling reliable data exchange with the cloud server, synchronizing tracker settings, and performing over-the-air updates.

In one embodiment, the battery management module comprises: a solar panel manager, an ultra-low-power DC-DC boost converter, a programmable maximum power point tracking (MPPT) controller, a programmable under-voltage protection circuit, and a programmable over-voltage protection circuit.

In one embodiment, the programmable over-voltage protection circuit is configured with a threshold up to about 4.3 V and the programmable under-voltage protection circuit is configured with a threshold down to about 2.5 V.

In one embodiment, the occupancy detection module is selected from a group consisting of a laser sensor, a camera, an ultrasonic sensor, and an infrared sensor.

In one embodiment, the vibration sensor module is a passive device that consumes substantially no power and is configured to trigger the system controller to wake the hybrid-powered asset tracking device from a sleep mode when a sudden movement exceeds a predetermined vibration threshold.

In one embodiment, the hybrid-powered asset tracking device further comprises a front case and a back case and one or more printed circuit boards (PCBs) enclosed by the front case and the back case. The system controller, the communication assembly, and the battery management module are disposed on the one or more PCBs.

In one embodiment, the hybrid-powered asset tracking device further comprises a shielding rubber disposed between the front case and the back case and configured to provide a seal that prevents ingress of water, gas, and dust.

In one embodiment, the primary battery module and the secondary battery module are disposed within an enclosure formed by the front case and the back case and are protected from environmental exposure by the shielding rubber.

In one embodiment, the system controller is further configured to place the asset tracking device into a deep sleep mode after production testing.

### BRIEF DESCRIPTION OF DRAWINGS

Embodiments of the invention are described in more details hereinafter with reference to the drawings, in which:

FIGS. 1A, 1B, 1C, and 1D illustrate a hybrid-powered asset tracking device according to some embodiments of the present invention;

FIGS. 2A, 2B, and 2C illustrate the shielding rubber of the hybrid-powered asset tracking device according to some embodiments of the present invention;

FIGS. 3A and 3B illustrate internal components disposed on the back case of the hybrid-powered asset tracking device according to some embodiments of the present invention;

FIGS. 4A, 4B, 4C, and 4D illustrate antenna modules, battery modules, and control circuitry of the hybrid-powered asset tracking device according to some embodiments of the present invention;

FIG. 5 illustrates an exploded view of the hybrid-powered asset tracking device according to some embodiments of the present invention;

FIG. 6 illustrates an architecture of a hybrid-powered asset tracking device according to some embodiments of the present invention; and

FIG. 7 is a diagram illustrating current flow directions in a hybrid-powered asset tracking device according to some embodiments of the present invention, depending on voltage level of the Li-ion rechargeable battery.

### DETAILED DESCRIPTION OF THE INVENTION:

In the following description, systems and methods configured for hybrid-powered asset tracking and the likes are set forth as preferred examples. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

In the present invention, a hybrid-powered asset tracking device is provided, which is a long-lifespan, hybrid-powered device designed to operate efficiently under various lighting conditions, including both high and low irradiance environments. The hybrid-powered asset tracking device utilizes a combination of power sources to maximize reliability and minimize maintenance needs. The primary function of the hybrid-powered asset tracking device is to determine and transmit its precise location, even in challenging environments, making it particularly suitable for tracking cargo and luggage carts. As used herein, the expression “long-lifespan” means a hybrid-powered asset tracking device can operate for at least 12 months without the need for maintenance or external charging/battery replacement.

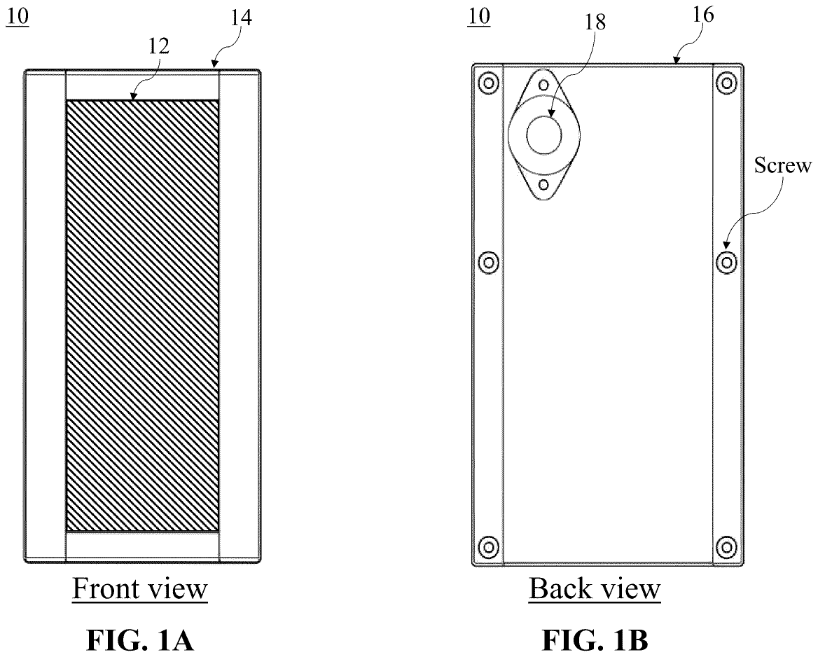

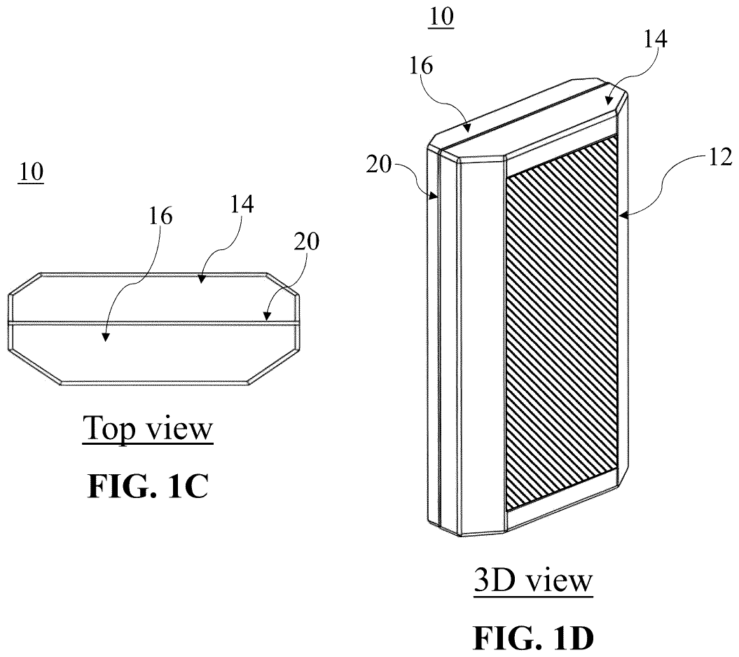

FIGS. 1A, 1B, 1C, and 1D illustrate a hybrid-powered asset tracking device 10 according to some embodiments of the present invention. The hybrid-powered asset tracking device 10 is capable of operating in diverse indoor and outdoor environments and includes a battery system with solar charging capabilities to power up the tracker across a wide temperature range (e.g., from −30° C. to +85° C.).

FIG. 1A shows a front view of the hybrid-powered asset tracking device 10; FIG. 1B shows a back view of the hybrid-powered asset tracking device 10; FIG. 1C shows a top view of the hybrid-powered asset tracking device 10; and FIG. 1D shows a perspective three-dimensional view of the hybrid-powered asset tracking device 10. The hybrid-powered asset tracking device 10 includes a solar panel 12, a front case 14, a back case 16, and a shielding rubber 20, which are integrated into a compact enclosure suitable for long-term outdoor and industrial applications.

The solar panel 12 is disposed on the front case 14 and configured to harvest light energy for supplying electrical power to the internal circuitry of the hybrid-powered asset tracking device 10. The solar panel 12 is further configured to support operation of the hybrid-powered asset tracking device 10 in diverse indoor and outdoor environments across a temperature range from −30° C. to +85° C. The solar panel 12 exhibits an efficiency rate of approximately 24% and is constructed to be waterproof and UV-resistant, thereby maintaining functionality under diverse outdoor conditions. The solar panel 12 is capable of delivering a maximum current output of approximately 170 mA at 2.97V, enabling sufficient power generation even under less-than-optimal lighting conditions.

The back case 16 is positioned opposite to the front case 14 and is configured to support an occupancy sensor 18 for detecting the presence of an object within a predefined perimeter. The front case 14 and the back case 16 are mechanically fastened together by screws, and a gasket of shielding rubber 20 is positioned between the front case 14 and the back case 16. The shielding rubber 20 is configured to provide an environmental seal that prevents ingress of gas and water into the hybrid-powered asset tracking device 10. Therefore, the hybrid-powered asset tracking device 10 is housed in a durable and weather-resistant casing, safeguarding the internal components from environmental factors such as moisture, dust, and physical impact. This rugged design allows the hybrid-powered asset tracking device 10 to be used in a variety of outdoor and industrial settings, particularly for tracking cargo or luggage carts that are frequently exposed to harsh conditions.

In one embodiment, the solar panel 12 is coupled with a Li-ion rechargeable battery having a capacity of less than 200 mAh. With optimal solar panel orientation toward sunlight, the Li-ion rechargeable battery can be fully charged within approximately one hour. The solar panel 12 is operatively coupled to a solar cell management system configured to extract solar energy under both high and low light irradiance. For example, the solar power management system can cold-start at about 600 mV from the solar panel 12 and thereafter continue harvesting at input levels down to about 130 mV, thereby allowing charging even when the panel is not directly facing the sun.

In one embodiment, the solar panel 12 includes a surface coating of ethylene tetrafluoroethylene (ETFE), the ETFE being configured to provide high corrosion resistance, durability across wide temperature ranges, and high spectral reflection for enhanced light utilization. The solar panel 12 further incorporates ethylene vinyl acetate (EVA) as an encapsulant material, the EVA being configured to provide adhesion to surrounding materials, high volume resistivity, optical transparency, mechanical strength, and UV resistance.

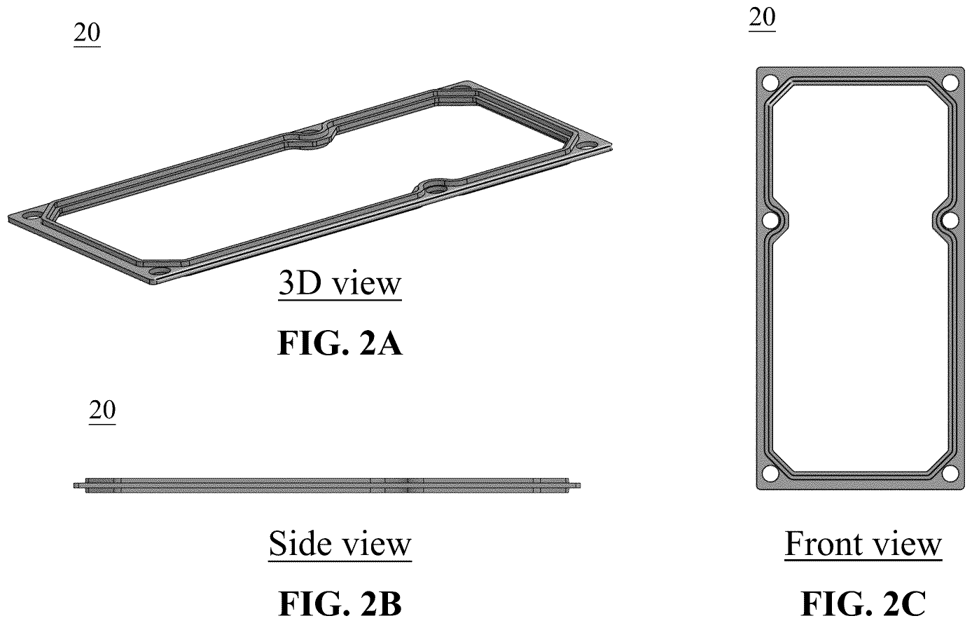

FIGS. 2A, 2B, and 2C illustrate the shielding rubber 20 of the hybrid-powered asset tracking device 10 according to some embodiments of the present invention. FIG. 2A provides a three-dimensional view of the shielding rubber 20; FIG. 2B provides a side view of the shielding rubber 20; and FIG. 2C provides a front view of the shielding rubber 20. The shielding rubber 20 is configured to be positioned between the front case 14 and the back case 16 of the device 10, and is further configured to provide an environmental seal that prevents ingress of water, dust, and gas into the internal enclosure.

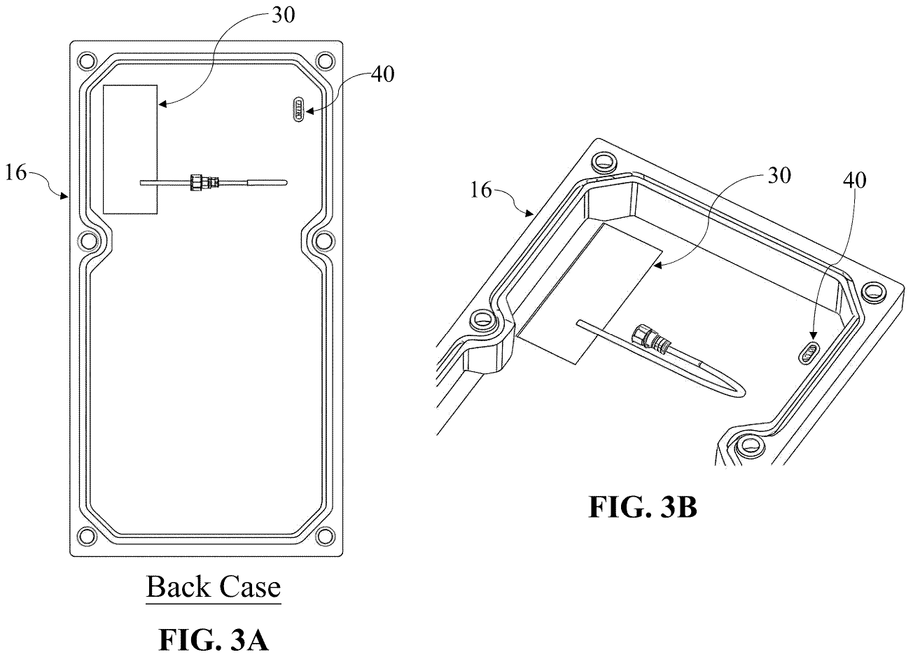

FIGS. 3A and 3B illustrate internal components disposed on the back case 16 of the hybrid-powered asset tracking device 10 according to some embodiments of the present invention. FIG. 3A provides a plan view of the back case 16, and FIG. 3B provides a perspective view of the back case 16. The hybrid-powered asset tracking device 10 further includes an NFC antenna 30 supported by the back case 16 and configured to enable near-field communication with an external reader. The NFC antenna 30 is further configured to activate the hybrid-powered asset tracking device 10 from a deep sleep or ex-factory mode. The hybrid-powered asset tracking device 10 further includes an occupancy sensor connector header 40 supported by the back case 16 and configured to interface with an occupancy sensor. The hybrid-powered asset tracking device 10 may include at least one occupancy sensor, when connected through the occupancy sensor connector header 40, configured to detect objects entering a predefined perimeter and to reduce the number of data exchanges with a remote server when no objects are detected.

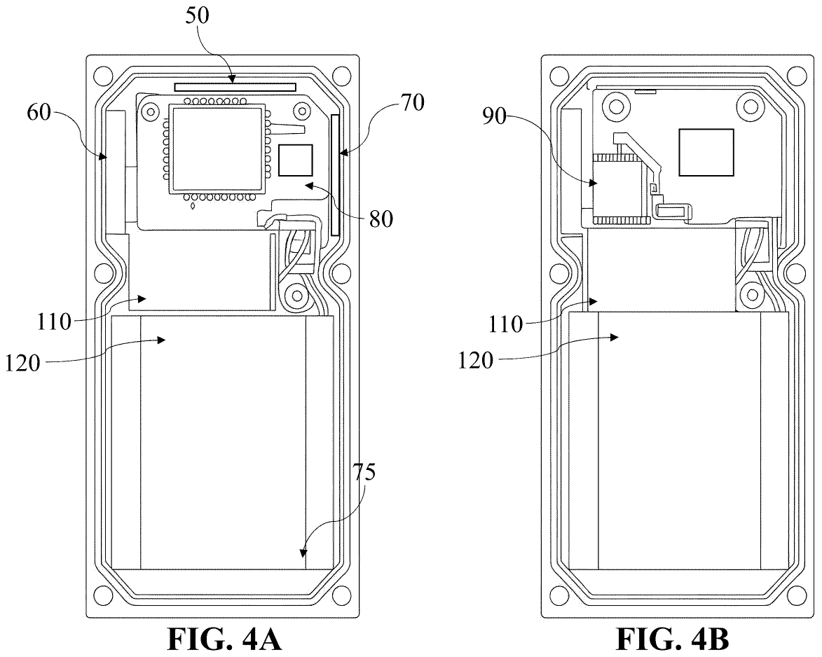

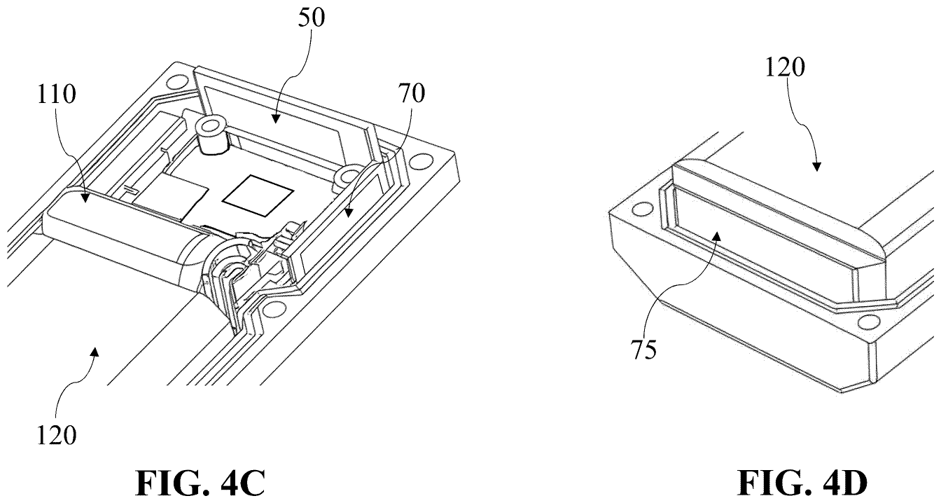

FIGS. 4A, 4B, 4C, and 4D illustrate antenna modules, battery modules, and control circuitry of the hybrid-powered asset tracking device 10 according to some embodiments of the present invention. FIG. 4A provides a plan view of the internal components; FIG. 4B provides another plan view showing additional circuitry; FIG. 4C provides a perspective view of the internal arrangement of the batteries and antennas; and FIG. 4D provides a perspective view of the lower portion of the enclosure with the cellular network antenna. In this regard, FIG. 4B illustrates a plan view of circuitry at a lower level, whereas FIG. 4C illustrates a perspective view showing the three-dimensional arrangement of the batteries and antennas.

The hybrid-powered asset tracking device 10 further includes a Bluetooth antenna 50, a GPS antenna 60, a Wi-Fi antenna 70, and a cellular network antenna 75 which are arranged within the back case 16. The Bluetooth antenna 50 is configured to provide short-range communication with external devices and to support indoor positioning. The GPS antenna 60 is configured to receive satellite signals from a Global Navigation Satellite System (GNSS) for determining an outdoor position. The Wi-Fi antenna 70 is configured to receive Wi-Fi access point signals for indoor positioning and data communication. The cellular network antenna 75 is configured to provide wide-area network connectivity for transmitting position information and sensor data to a remote server over NB-IoT, 4G, or 5G networks.

The hybrid-powered asset tracking device 10 further includes a secondary battery 110 and a primary battery 120 which are interconnected with a battery management system positioned on printed circuit boards (PCBs) 80 and 90. In one embodiment, the primary battery 120 is configured as a bundled pack of three non-rechargeable lithium-thionyl chloride (Li/SOCl₂) cells having a total capacity of not less than 8000mAh. The primary battery 120 provides a high energy density, long shelf life, wide operating temperature range, and low self-discharge characteristics, enabling the hybrid-powered asset tracking device 10 to operate for extended periods without replacement. In one embodiment, the secondary battery 110 is configured as a Lithium-ion (Li-ion) rechargeable battery of size 1520 or 1530, having a capacity of about 100 mAh to 200 mAh. The secondary battery 110 is configured to provide high C-rate pulse discharge, thereby supplying sufficient instantaneous current for power-hungry functions such as data transmission to the remote server over cellular networks. The secondary battery 110 is further configured to store harvested energy from the solar panel 12, thereby extending overall operating lifespan of the hybrid-powered asset tracking device 10.

In some embodiments, the primary battery 120 is operatively coupled through a Schottky diode to provide charging current to the secondary battery 110 when the voltage of the secondary battery 110 falls below a predetermined threshold. This configuration enables the primary battery 120 to maintain the secondary battery 110 in an operational state without requiring additional voltage conversion circuitry.

The chipset mounted on PCB 80 comprises a BLE module with integrated microprocessor functionality, a Wi-Fi module, a GNSS module, and a cellular module. The BLE module is configured to handle short-range communication and system control. The Wi-Fi module is configured to facilitate indoor positioning and data transfer via Wi-Fi access points. The GNSS module is configured to acquire GPS, GLONASS, BDS, or GALILEO signals for outdoor positioning. The cellular module is configured to support NB-IoT, 4G, or 5G communication technologies, thereby enabling transmission of device position and condition data to a server over the internet. The chipset modules collectively enable the device 10 to operate in both indoor and outdoor environments by dynamically selecting the most appropriate positioning and communication technology.

As shown in FIGS. 4C and 4D, the secondary battery 110 is disposed adjacent to the primary battery 120, with the Bluetooth antenna 50 and the Wi-Fi antenna 70 arranged above the batteries within the front case 14. At the lower portion of the enclosure, the primary battery 120 is positioned proximate to the cellular network antenna 75, which provides wide-area connectivity for data exchange with a remote server.

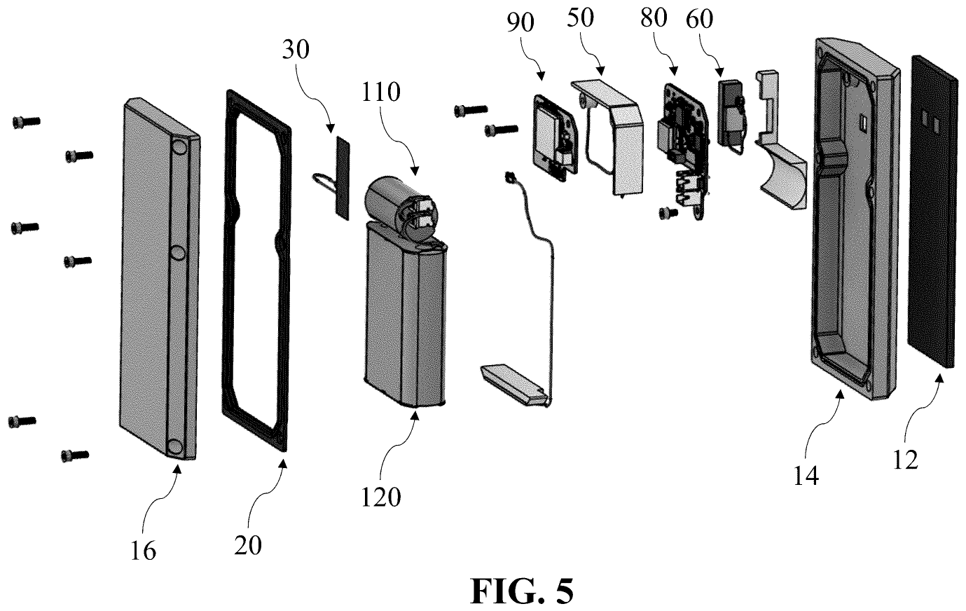

FIG. 5 illustrates an exploded view of the hybrid-powered asset tracking device 10 according to some embodiments of the present invention. The figure shows the front case 14, the back case 16, the solar panel 12, and the shielding rubber 20, together with internal components including the NFC antenna 30, the secondary battery 110, the primary battery 120, and the printed circuit boards 80 and 90 carrying antenna and control circuitry. The exploded view demonstrates the general structural arrangement of the hybrid-powered asset tracking device 10 without limiting the specific assembly sequence or configuration.

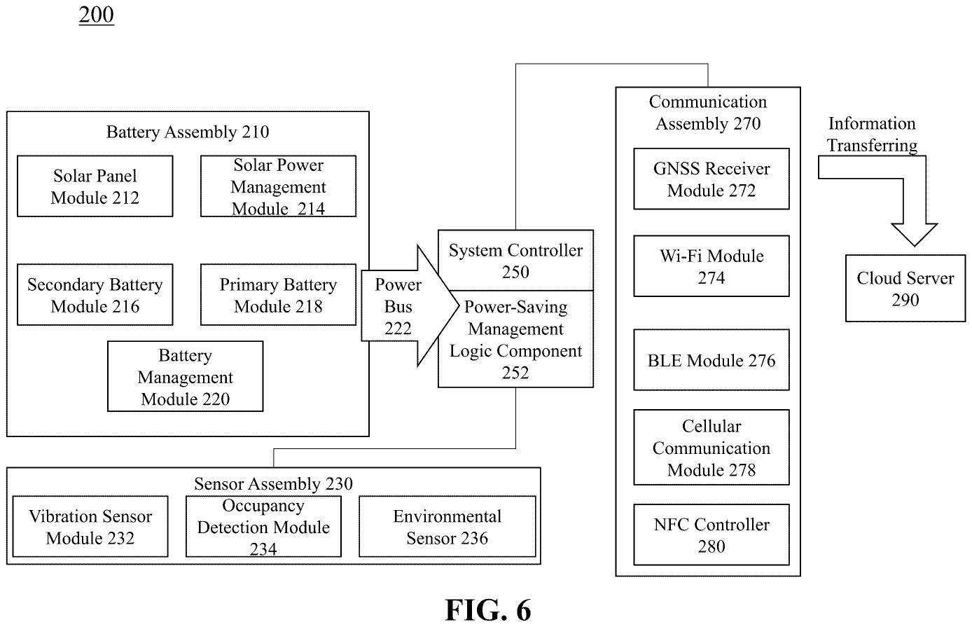

FIG. 6 illustrates an architecture of a hybrid-powered asset tracking device 200 according to some embodiments of the present invention. The hybrid-powered asset tracking device 200 serves as a long-lifespan hybrid-powered asset tracker with solar charging capabilities under both high and low light irradiance conditions. The hybrid-powered asset tracking device 200 in FIG. 6 further shows interconnections and communication relationships among the components, as well as control operations performed by certain components. The hybrid-powered asset tracking device 200 includes a battery assembly 210, a sensor assembly 230, a system controller 250 incorporating power-saving management logic component 252, and a communication assembly 270, all electrically coupled through buses and signal interfaces. For example, the battery assembly 210 is electrically coupled to the system controller 250 through a power bus 222.

The battery assembly 210 includes a solar panel module 212, a solar power management module 214, a secondary battery module 216, a primary battery module 218, and a battery management module 220.

The solar panel module 212 is configured to harness sunlight and convert it to electrical energy. The solar panel module 212 is formed of high-efficiency monocrystalline cells and is weatherproof and UV-resistant. In one embodiment, the solar panel module 212 provides an efficiency of about 24% and a maximum output current of at least 80 mA (e.g., about 170 mA at 2.97 V). The solar panel module 212 supplies energy to the solar power management module 214 and provides charging current to the secondary battery module 216.

The solar power management module 214 is configured to condition and harvest energy from the solar panel module 212. The solar power management module 214 incorporates an ultra-low-power DC-DC boost converter and a programmable maximum power point tracking (MPPT) controller. In one embodiment, the solar power management module 214 supports a broad input range from about 0.13 V to about 3.7 V, cold-starts at about 600 mV, and continues harvesting at input levels down to about 130 mV. The MPPT controller is configurable (for example MPPT ratio 70% or 80%) to optimize extraction and can reach about 90% efficiency at 3 V. In one embodiment, the solar power management module 214 further includes programmable under-voltage and over-voltage protection circuits, with thresholds configurable down to about 2.5 V and up to about 4.3 V, respectively, thereby protecting against abnormal operating conditions. The solar power management module 214 delivers regulated charging power to the secondary battery module 216 and, when energy is available, concurrently powers the communication assembly 270.

The secondary battery module 216 is a li-ion rechargeable battery (for example size 1520 or 1530 having a capacity of about 100-200 mAh) and configured to supply high C-rate pulse current for power-hungry operations such as cellular data uplink. The secondary battery module 216 receives charging energy from the solar power management module 214 and from the primary battery module 218 and delivers operating power to the system controller 250.

The primary battery module 218 is configured as one or more non-rechargeable lithium-thionyl chloride (Li/SOCl₂) cells (e.g., a three-cell bundle providing not less than 8000 mAh) which may be suitable for a temperature range from about −55° C. to +85° C. The primary battery module 218 is coupled to the secondary battery module 216 through a low-forward-voltage Schottky diode to provide unidirectional current flow. When a voltage of the secondary battery module 216 drops below a threshold defined by the primary battery voltage plus the diode drop, the primary battery module 218 provides charging current to the secondary battery module 216. This configuration omits additional step-up or step-down converters, thereby simplifying the circuit.

The battery management module 220 monitors state of charge of the solar panel module 212, the primary battery module 218, and the secondary battery module 216, controls charging of the secondary battery module 216 from the solar power management module 214 and from the primary battery module 218, selects an active power source, and feeds the power bus 222. The battery management module 220 reports energy availability and protection status to the system controller 250.

In one embodiment, the secondary battery module 216 is further characterized by an operating temperature range from about −40° C. to about +85° C., thereby enabling stable operation under harsh environmental conditions (while individual components may support wider temperature ranges, the guaranteed operational temperature of the device is limited to the system-level specification).

The battery management module 220 further includes an intelligent power management system configured to monitor the charge levels of the solar panel module 212, the secondary battery module 216, and the primary battery module 218, and to dynamically adjust power consumption based on energy availability. Under favorable irradiance conditions, the solar panel module 212 is configured to provide sufficient energy not only to charge the secondary battery module 216 but also to directly power selected subsystems (e.g., the components of the sensor assembly 230 and the communication assembly 270), thereby extending the overall operating lifespan of the hybrid-powered asset tracking device 200.

The sensor assembly 230 includes a vibration sensor module 232, an occupancy detection module 234, and optional environmental sensors 236.

The vibration sensor module 232 is a passive device that draws substantially no power in idle states and outputs a wake-up trigger to the system controller 250 when a sudden movement exceeds a predefined threshold. In response, the power-saving management logic component 252 may resume communication or positioning; when no movement is detected for a specified period, the power-saving management logic component 252 limits a number of data exchanges between the hybrid-powered asset tracking device 200 and a remote server, thereby conserving energy and extending device lifespan, and also keeps the hybrid-powered asset tracking device 200 in deep sleep. This approach provides advantages over gyroscopes (which draw a few mA) and accelerometers (which draw a few hundred μA) that consume continuous power.

The occupancy detection module 234, which may be implemented with a laser sensor, a camera, an ultrasonic sensor, or an infrared sensor, is configured to output an occupancy signal to the system controller 250. For example, when an ultrasonic sensor detects that no object is present within a predefined perimeter, the power saving management logic 252 is configured to reduce or suspend data exchanges with a remote server in order to conserve energy. In one embodiment, compared to GNSS scanning which consumes about 25 mA, Wi-Fi scanning which consumes about 70 mA, and BLE scanning which consumes about 10 mA, the use of the occupancy detection module 234 as a criterion for initiating location tracking significantly reduces overall current consumption.

The environmental sensors 236, which may include temperature, humidity, pressure, or light sensors, are configured to provide condition data to the system controller 250 for cargo monitoring. For example, when a temperature sensor detects that the temperature inside a container exceeds a predefined threshold, the system controller 250 is configured to generate an alert signal and to transmit this condition data to the remote server for further action.

The system controller 250 receives the energy from the power bus 222 and orchestrates device operation. The system controller 250 selects power-use modes based on telemetry from the battery management module 220, manages charging priorities (solar first, battery backup when solar is insufficient), schedules tasks, and executes the power-saving management logic component 252. The system controller 250 sets a time limit for the GNSS receiver module 272 to compute a position solution to avoid excessive energy draw in obstructed-sky conditions; after a fix the hybrid-powered asset tracking device 200 enters an idle state with minimum current, where only a timer and the vibration sensor module 232 remain active, the GNSS receiver module 272 enters a backup mode, and the cellular communication module 278 operates in a power-saving mode (PSM). In some embodiments, the system controller 250 is implemented by, or operates in coordination with, the microcontroller integrated in the communication assembly 270. In some embodiments, the system controller 250 is implemented by, or tightly coupled with, the microcontroller integrated in the communication assembly 270.

The communication assembly 270 includes a GNSS receiver module 272, a Wi-Fi module 274, a Bluetooth low energy (BLE) module 276, a cellular communication module 278, and an NFC controller 280.

The GNSS receiver module 272 is configured to receive satellite signals and navigation data from GPS, GLONASS, BDS, and GALILEO and, with Assisted-GPS support, to acquire a cold-start fix in under about 5.5 seconds and a hot-start fix in about 2 seconds.

The Wi-Fi module 274 and BLE module 276 are configured to detect Wi-Fi access points and Bluetooth beacons for indoor positioning and to exchange data with the system controller 250. Moreover, the Wi-Fi module 274 is capable of transmitting position information (e.g., the indoor positioning information) to a cloud server 290.

The cellular communication module 278 provides NB-IoT/4G/5G wide-area connectivity, uploads telemetry to the cloud server 290 over a communication link, synchronizes settings, and supports over-the-air updates.

In some embodiments, the Wi-Fi module 274 and the cellular communication module 278 are operated in a selectable manner such that either module is used individually or both are operated in parallel. For example, users may select either the Wi-Fi network provided by the Wi-Fi module 274 or the cellular network provided by the cellular communication module 278 as the primary network/channel for data transmission, and optionally configure another one of them as a backup in the event that the primary network/channel is unavailable.

The NFC controller 280 exchanges data with an NFC reader and provides an activation signal to the system controller 250 to wake the hybrid-powered asset tracking device 200 from a deep-sleep or ex-factory mode for deployment.

In one embodiment, the communication assembly 270 is implemented as an integrated chipset disposed on a printed circuit board, the chipset comprising the BLE module 276 with microprocessor functionality, the Wi-Fi module 274, the GNSS receiver module 272, and the cellular communication module 278. The chipset is configured to receive indoor BLE, Wi-Fi, and cellular network signals, and outdoor GPS or BeiDou satellite signals, and to transmit position information to a remote server via the cellular communication module 278. The positioning operation is adaptive, wherein the GNSS receiver module 272 is prioritized in outdoor environments, the Wi-Fi module 274 and BLE module 276 are employed for indoor positioning, and the cellular communication module 278 is utilized for fallback positioning when GNSS, Wi-Fi, and BLE signals are unavailable. In one embodiment, the cellular communication module 278 supports the PSM to reduce energy consumption during idle states. The NFC controller 280 further provides power saving functionality by enabling a shipping mode during transportation and storage to prevent unnecessary battery drain, and by enabling specific control functions such as starting or stopping position tracking in rental applications.

In one embodiment, the hybrid-powered asset tracking device 200 is configured with a deep sleep mode to minimize energy consumption during storage and transportation after production. Following production testing, the device 200 automatically enters a non-active state with a standby current of about 50 μA, thereby allowing the battery packs to retain more than 95% of their capacity after one year of storage. When the hybrid-powered asset tracking device 200 is to be installed on an asset for tracking, the device can be activated from the deep sleep mode into a normal operation mode by the system controller 250 upon receiving an activation command from the NFC controller 280. In one example, a user may utilize a smartphone to enter an asset identifier and cloud server information, and by placing the smartphone in proximity to the hybrid-powered asset tracking device 200, the NFC controller 280 establishes data transmission and completes the activation process.

In operation, the solar panel module 212 is the primary energy source and charges the secondary battery module 216 through the solar power management module 214; the primary battery module 218 serves as a backup energy source and, when required, charges the secondary battery module 216 through the Schottky path. The secondary battery module 216 supplies the power bus 222, which in turn powers the system controller 250, the sensor assembly 230, and the communication assembly 270. The system controller 250 selects a positioning strategy based on environment: GNSS data outdoors; Bluetooth iBeacon and Wi-Fi access-point data indoors; cellular positioning when GNSS, iBeacon, and Wi-Fi signals are unavailable. Depending on device status, harvested solar energy can simultaneously power the GNSS receiver module 272 and the BLE module 276 while charging the secondary battery module 216. The sensor assembly 230 provides motion, occupancy, and environmental information to the system controller 250, which schedules reporting; when no motion or occupancy is detected, the controller 250 limits server exchanges and maintains the hybrid-powered asset tracking device 200 in deep sleep. Data and status generated by the system controller 250 are delivered to the cloud server 290 via the communication assembly 270.

In one aspect, the hybrid-powered asset tracking device 200 achieves an extended operational lifespan through the cooperative operation of the primary battery module 218, the secondary battery module 216, and the Schottky diode coupling. The primary battery module 218 provides long-term baseline energy and, when the voltage of the secondary battery module 216 falls below a threshold, supplies charging current through the Schottky diode without requiring step-up or step-down converters. In parallel, the solar panel module 212 and the solar power management module 214 charge the secondary battery module 216 whenever light energy is available. The cooperative relationship between the primary battery module 218, the secondary battery module 216, and the solar energy harvesting path ensures that the secondary battery module 216 is consistently maintained in an operational state, thereby enabling the hybrid-powered asset tracking device 200 to sustain both low-power idle conditions and high-current communication bursts for long durations.

In another aspect, the hybrid-powered asset tracking device 200 incorporates a power saving strategy based on the cooperative function of the vibration sensor module 232 and the occupancy detection module 234. The vibration sensor module 232 outputs a wake-up trigger to the system controller 250 only when a sudden movement exceeding a threshold is detected, and the occupancy detection module 234 outputs an occupancy signal to the system controller 250 only when an object is present within a predefined area. The power-saving management logic component 252 coordinates these sensor signals to determine when to suspend or resume data exchanges with the remote server. This cooperative relationship allows the hybrid-powered asset tracking device 200 to eliminate unnecessary server communication in periods of no movement and no occupancy, thereby substantially reducing energy consumption compared with conventional continuous sensing and reporting methods.

In a further aspect, the hybrid-powered asset tracking device 200 enhances energy efficiency and connectivity reliability through the cooperative operation of the solar power management module 214, the system controller 250, and the cellular communication module 278. The solar power management module 214 maximizes energy harvesting from the solar panel module 212 using MPPT and low-voltage harvesting, while the system controller 250 with power-saving management logic component 252 dynamically adjusts the duty cycle of positioning and communication based on sensor input. The cellular communication module 278 supports the PSM, enabling long standby times with minimal current draw. The cooperative interaction among the solar energy harvesting path, the control logic, and the communication assembly ensures that the hybrid-powered asset tracking device 200 remains capable of transmitting essential tracking information while conserving power across both indoor and outdoor environments.

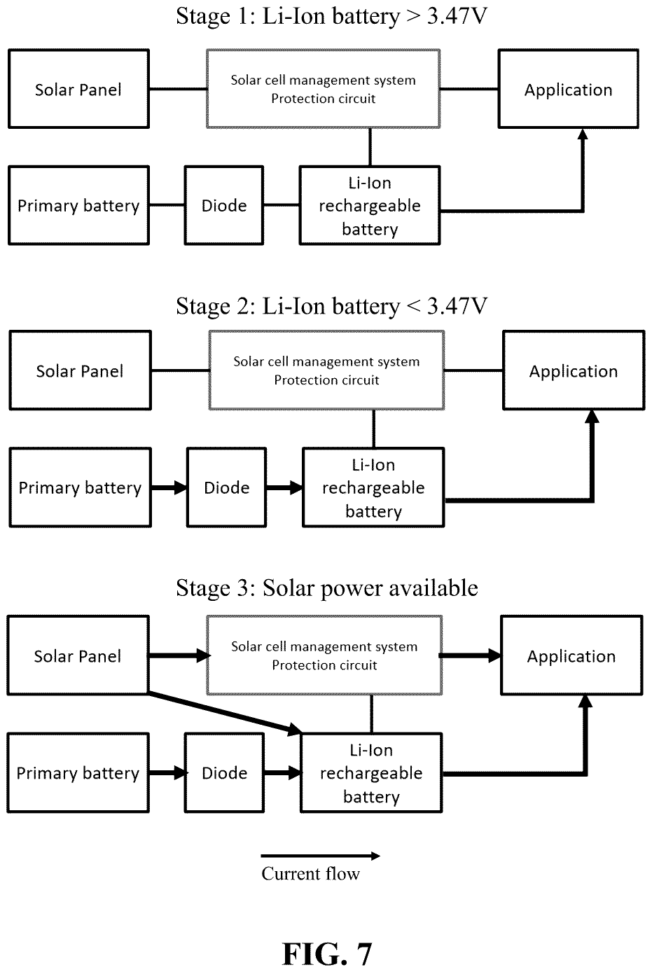

FIG. 7 is a diagram illustrating current flow directions in a hybrid-powered asset tracking device according to some embodiments of the present invention, depending on voltage level of the Li-ion rechargeable battery. The operation has three distinct stages and can seamlessly transition between them without requiring sequential progression. In one embodiment, the operation is performed by the hybrid-powered asset tracking device 200 and is directed and scheduled by the system controller 250.

In stage 1, when the Li-ion rechargeable battery is above 3.47 V and no solar energy is available (if solar energy is available, it enters stage 3), the Li-ion rechargeable battery serves as the sole power source and provides operating current to the application circuitry. In terms of the device architecture of FIG. 6, this operation involves the cooperative function of the secondary battery module 216 delivering power through the power bus 222 to the system controller 250, the sensor assembly 230, and the communication assembly 270, thereby sustaining all active subsystems.

In stage 2, when the voltage of the Li-ion rechargeable battery drops below 3.47 V, the primary battery begins charging the rechargeable battery. The charging current is determined by the voltage difference between the primary battery and the Li-ion battery, minus the forward voltage drop across the Schottky diode. In the device architecture of FIG. 6, this operation involves the primary battery module 218 cooperating with the secondary battery module 216 through the diode, under monitoring of the battery management module 220, so that the secondary battery module 216 is maintained in a charged state and can continue to support the system controller 250 and the communication assembly 270 for normal operation.

In stage 3, when solar energy is available, solar power is harvested and converted to electrical energy by the solar power management module 214, which incorporates a step-up converter and protection circuit. The harvested energy is simultaneously directed to charge the Li-ion rechargeable battery and to supply current to the application circuitry. In the device architecture of FIG. 6, this stage involves cooperative operation of the solar panel module 212, the solar power management module 214, and the secondary battery module 216, with the battery management module 220 regulating charge flow. The solar energy provides direct power to the power bus 222, enabling the system controller 250 and the communication assembly 270, such as the GNSS receiver module 272 and BLE module 276, to operate while the secondary battery module 216 is recharged.

It should be noted that the above-mentioned examples are merely intended for description of the technical solutions of the present disclosure rather than limitation of the present disclosure. Although the present disclosure is described in detail with reference to the preferred examples, those of ordinary skill in the art should understand that they may still make modifications or equivalent replacements to the technical solutions of the present disclosure without departing from the spirit and scope of the technical solutions of the present disclosure, all of which should be encompassed within the scope of the claims of the present disclosure.

Several embodiments of the present disclosure and features of details are briefly described above. The embodiments described in the present disclosure may be easily used as a basis for designing or modifying other processes and structures for realizing the same or similar objectives and/or obtaining the same or similar advantages introduced in the embodiments of the present disclosure. Such equivalent construction does not depart from the spirit and scope of the present disclosure, and various variations, replacements, and modifications can be made without departing from the spirit and scope of the present disclosure.

As used herein, terms “approximately”, “basically”, “substantially”, and “about” are used for describing and explaining a small variation. When being used in combination with an event or circumstance, the term may refer to a case in which the event or circumstance occurs precisely, and a case in which the event or circumstance occurs approximately. As used herein with respect to a given value or range, the term “about” generally means in the range of ±10%, ±5%, ±1%, or ±0.5% of the given value or range. The range may be indicated herein as from one endpoint to another endpoint or between two endpoints. Unless otherwise specified, all the ranges disclosed in the present disclosure include endpoints. The term “substantially coplanar” may refer to two surfaces within a few micrometers (μm) positioned along the same plane, for example, within 10 μm, within 5 μm, within 1 μm, or within 0.5 μm located along the same plane. When reference is made to “substantially” the same numerical value or characteristic, the term may refer to a value within ±10%, ±5%, ±1%, or ±0.5% of the average of the values.

The functional units and modules of the systems and methods in accordance with the embodiments disclosed herein may be implemented using computing devices, computer processors, or electronic circuitries including but not limited to application specific integrated circuits (ASIC), field programmable gate arrays (FPGA), microcontrollers, and other programmable logic devices configured or programmed according to the teachings of the present disclosure. Computer instructions or software codes executing in the computing devices, computer processors, or programmable logic devices can readily be prepared by practitioners skilled in the software or electronic art based on the teachings of the present disclosure.

All or portions of the methods in accordance with the embodiments may be executed in one or more computing devices including server computers, personal computers, laptop computers, mobile computing devices such as smartphones and tablet computers.

The embodiments may include computer storage media, transient and non-transient memory devices having computer instructions or software codes stored therein, which can be used to program or configure the computing devices, computer processors, or electronic circuitries to perform any of the processes of the present invention. The storage media, transient and non-transient memory devices can be included, but are not limited to, floppy disks, optical discs, Blu-ray Disc, DVD, CD-ROMs, and magneto-optical disks, ROMs, RAMs, flash memory devices, or any type of media or devices suitable for storing instructions, codes, and/or data.

Each of the functional units and modules in accordance with various embodiments also may be implemented in distributed computing environments and/or Cloud computing environments, wherein the whole or portions of machine instructions are executed in distributed fashion by one or more processing devices interconnected by a communication network, such as an intranet, Wide Area Network (WAN), Local Area Network (LAN), the Internet, and other forms of data transmission medium.

What is claimed is:

1. A long-lifespan hybrid-powered asset tracking device with solar charging capabilities operable under both high and low light irradiance conditions, comprising:
a system controller comprising a power-saving management logic component;
a communication assembly coupled to the system controller and configured to provide location determination and data exchange for the asset tracking device in indoor and/or outdoor environments;
a battery assembly coupled to the system controller and comprising a solar panel module, a primary battery module, a secondary battery module, and a battery management module, wherein the battery management module is configured to charge the secondary battery module using energy from the solar panel module and the primary battery module;
a vibration sensor module coupled to the system controller and configured to detect movement of the asset tracking device, wherein the power-saving management logic component is configured to cooperate with the vibration sensor module to limit a number of data exchanges between the asset tracking device and a cloud server when the vibration sensor module determines that no movement of the asset tracking device is present; and
an occupancy detection module coupled to the system controller and configured to detect whether an object is present within a predefined perimeter and to limit a number of data exchanges between the asset tracking device and the cloud server using the power-saving management logic component when no objects are detected.

2. The hybrid-powered asset tracking device of claim 1, wherein the communication assembly comprises a GNSS receiver module configured to obtain satellite signals from GPS, GLONASS, BDS, or GALILEO.

3. The hybrid-powered asset tracking device of claim 2, wherein the GNSS receiver module supports Assisted GPS (A-GPS) and is configured to obtain a cold-start position fix in under about 5.5 seconds and a hot-start position fix in under about 2 seconds.

4. The hybrid-powered asset tracking device of claim 2, wherein the communication assembly comprises a Wi-Fi module configured to detect Wi-Fi access points for indoor positioning and data exchange.

5. The hybrid-powered asset tracking device of claim 4, wherein the communication assembly comprises a Bluetooth Low Energy (BLE) module configured to detect Bluetooth beacons for indoor positioning and data exchange.

6. The hybrid-powered asset tracking device of claim 5, wherein the communication assembly comprises a cellular communication module configured to provide NB-IoT, 4G, or 5G connectivity for uploading telemetry to the cloud server.

7. The hybrid-powered asset tracking device of claim 6, wherein the cellular communication module supports a power saving mode (PSM) to reduce current consumption during idle states.

8. The hybrid-powered asset tracking device of claim 6, further comprising:
an NFC controller coupled to the system controller and configured to exchange data with an NFC reader and to activate the asset tracking device from a deep sleep mode or an ex-factory mode.

9. The hybrid-powered asset tracking device of claim 8, wherein the communication assembly is configured to provide multiple communication options including Wi-Fi, BLE, and a cellular network, thereby enabling reliable data exchange with the cloud server, synchronizing tracker settings, and performing over-the-air updates.

10. The hybrid-powered asset tracking device of claim 1, wherein the battery management module comprises:
a solar panel manager;
an ultra-low-power DC-DC boost converter;
a programmable maximum power point tracking (MPPT) controller;
a programmable under-voltage protection circuit; and
a programmable over-voltage protection circuit.

11. The hybrid-powered asset tracking device of claim 10, wherein the programmable over-voltage protection circuit is configured with a threshold up to about 4.3 V and the programmable under-voltage protection circuit is configured with a threshold down to about 2.5 V.

12. The hybrid-powered asset tracking device of claim 1, wherein the occupancy detection module is selected from a group consisting of a laser sensor, a camera, an ultrasonic sensor, and an infrared sensor.

13. The hybrid-powered asset tracking device of claim 1, wherein the vibration sensor module is a passive device that consumes substantially no power and is configured to trigger the system controller to wake the hybrid-powered asset tracking device from a sleep mode when a sudden movement exceeds a predetermined vibration threshold.

14. The hybrid-powered asset tracking device of claim 1, further comprising:
a front case and a back case; and
one or more printed circuit boards (PCBs) enclosed by the front case and the back case, wherein the system controller, the communication assembly, and the battery management module are disposed on the one or more PCBs.

15. The hybrid-powered asset tracking device of claim 14, further comprising a shielding rubber disposed between the front case and the back case and configured to provide a seal that prevents ingress of water, gas, and dust.

16. The hybrid-powered asset tracking device of claim 15, wherein the primary battery module and the secondary battery module are disposed within an enclosure formed by the front case and the back case and are protected from environmental exposure by the shielding rubber.

17. The hybrid-powered asset tracking device of claim 1, wherein the system controller is further configured to place the asset tracking device into a deep sleep mode after production testing.
